(19) United States
(12) Patent Application Publication
(10) Pub. No.: US 2016/0133572 A1
(43) Pub. Date: May 12, 2016

(54) METHODS OF FORMING A PROTECTIVE LAYER ON AN INSULATING LAYER FOR PROTECTION DURING FORMATION OF CONDUCTIVE STRUCTURES

(71) Applicants: GLOBALFOUNDRIES Inc., Grand Cayman (KY); International Business Machines Corporation, Armonk, NY (US)

(72) Inventors: Xunyuan Zhang, Albany, NY (US); Wei Lin, Albany, NY (US)

(21) Appl. No.: 14/536,083

(22) Filed: Nov. 7, 2014

(51) Int. Cl. H01L 23/532; H01L 21/02; H01L 21/768; H01L 21/033; H01L 23/528; H01L 21/3213

(52) U.S. Cl. CPC H01L 23/53238; H01L 23/528; H01L 21/32139; H01L 21/7684; H01L 21/76877; H01L 21/76841; H01L 21/0332; H01L 21/0337; H01L 21/02164; H01L 21/0217

(57) ABSTRACT

One illustrative method disclosed herein includes, among other things, performing at least one etching process through an overall masking layer to define an opening in a layer of insulating material, wherein the overall masking layer is comprised of a patterned metal-silicate masking layer that is positioned on and in contact with the layer of insulating material and a patterned masking layer positioned on and in contact with the patterned metal-silicate masking layer, over-filling the opening with a conductive material and performing at least one planarization process so as to remove excess materials positioned outside of the opening above the patterned metal-silicate masking layer and thereby define a conductive structure that is positioned in the opening.

### BACKGROUND OF THE INVENTION

1. Field of the Invention

Generally, the present disclosure relates to the manufacture of semiconductor devices, and, more specifically, to various methods of forming a protection layer on a layer of insulating material so as to protect the layer of insulating material when conductive structures are formed in the layer of insulating material, and an integrated circuit product that includes such a protection layer.

2. Description of the Related Art

In modern integrated circuits, such as microprocessors, storage devices and the like, a very large number of circuit elements, especially transistors, are provided and operated on a restricted chip area Immense progress has been made over recent decades with respect to increased performance and reducing the physical size (feature sizes) of circuit elements, such as transistors. Field effect transistors (FETs) come in a variety of configurations, e.g., planar transistor devices, FinFET devices, nanowire devices, etc. Irrespective of the form of the FET, they have a gate electrode, a source region, a drain region and a channel region positioned between the source and drain regions. The state of the field effect transistor (“ON” or “OFF”) is controlled by the voltage applied to the gate electrode. Upon the application of an appropriate control voltage to the gate electrode, the channel region becomes conductive, thereby allowing current to flow between the source and drain regions.

Typically, due to the large number of circuit elements and the required complex layout of modern integrated circuits, the electrical connections of the individual circuit elements cannot be established within the same device level on which the circuit elements are manufactured. Rather, integrated circuit products typically have one or more additional metallization layers, which generally include metal-containing lines providing the intra-level electrical connection, and also include a plurality of inter-level connections or vertical connections, which are also referred to as vias. These vertical interconnect structures comprise an appropriate metal and provide the electrical connection of the various stacked metallization layers.

Furthermore, in order to actually connect the circuit elements formed in the semiconductor material with the metallization layers, an appropriate vertical contact structure is provided, a first lower end of which is connected to a respective contact region of a circuit element, such as a gate electrode and/or the drain and source regions of transistors, and a second end is connected to a respective metal line in the metallization layer by a conductive via. Such vertical contact structures are considered to be “device-level” contacts or simply “contacts” within the industry, as they contact the “device” that is formed in the silicon substrate. The contact structures may comprise contact elements or contact plugs having a generally square-like or round shape that are formed in an interlayer dielectric material, which in turn encloses and passivates the circuit elements. In other applications, the contact structures may be line-type features, e.g., source/drain contact structures.

FIGS. 1A-1D depict an illustrative prior art hard mask layer used in forming conductive structures in a layer of insulating material and some problems that may be encountered using such prior art processing techniques. FIG. 1A is a simplified view of an illustrative prior art device 10 that includes a patterned layer of insulating material 14 formed above an underlying etch stop layer 12. A bi-layer patterned hard mask layer is formed above the layer of insulating material 14. In the depicted example, the bi-layer patterned hard mask layer is comprised of a sacrificial layer 24 and a layer of titanium nitride layer 22 formed thereabove. In one embodiment, the sacrificial layer 24 may be made of silicon nitride that contains hydrogen. The thickness of the various layers of material 14, 22 and 24 may vary depending upon the particular application. FIG. 1A also depicts the device 10 after at least one etching process has been performed through the bi-layer hard mask layer to form a plurality of metallization openings 16 in the layer of insulating material 14. The etching process stops on the etch stop layer 12. The openings 16 may be for metal lines and/or conductive vias. Although the layer of insulating material 14 is simplistically depicted as being a single layer of material, in practice, the layer of insulating material 14 may be comprised of a plurality of layers of insulating material, perhaps with an intervening etch stop layer formed between such layers of material.

As shown in FIG. 1B, the patterned hard mask layer will eventually be removed from above the patterned layer of insulating material 14. The patterned hard mask layer is removed to eliminate undercutting under the hard mask and to reduce the aspect ratio of the openings 16, thereby making them easy to fill without creating voids.

FIG. 1C depicts the device 10 after several process operations were performed. First, a schematically depicted barrier layer/adhesion layer 30 was formed on the device 10 and in the openings 16. In one embodiment, the barrier layer/adhesion layer 30 may be comprised of a first barrier layer (not separately shown) of tantalum nitride and a second adhesion layer (not separately shown) made of tantalum, both of which may be formed by performing sequential conformal deposition processes, e.g., atomic layer deposition (ALD), physical vapor deposition (PVD), etc. After the barrier layer/adhesion layer 30 is formed, a bulk conductive material layer 32, such as a copper-based material, is formed in the openings 16. Other materials, such as cobalt and ruthenium, may be employed as part of the barrier layer/adhesion layer 30.

FIG. 1D depicts the device 10 after one or more chemical mechanical planarization (CMP) process operations were performed to remove the excess conductive materials positioned outside of the openings 16 above the upper surface of the layer of insulating material 14. Unfortunately, especially in cases where the layer of insulating material 14 is comprised of a low-k (k value less than 3.5) insulating material or an ultra-low-k (ULK) insulating material (k value less than 3.2), the above-described process operations may cause many problems. More specifically, during the last of the CMP operations, the patterned layer of insulating material 14 is exposed to the chemicals that are used in the CMP process. Especially in the case where the patterned layer of insulating material 14 is a relatively porous low-k material or a ULK material, the chemical used in the CMP process may penetrate into the patterned layer of insulating material. Additionally, during the CMP process, some portion of the thickness of the layer of insulting material is consumed. This is especially true for low-k and ULK materials that are not as mechanically strong as other insulating materials, e.g., silicon dioxide. As indicated in FIG. 1D, at the end of the CMP process operations, the overall height or thickness 14H of the patterned layer 14 is significantly less than the original patterned layer of insulating material 14.

The present disclosure is directed to various methods of forming a protection layer on a layer of insulating material so as to protect the layer of insulating material when conductive structures are formed in the layer of insulating material, and an integrated circuit product that includes such a protection layer, that may solve or at least reduce some of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming a protection layer on a layer of insulating material so as to protect the layer of insulating material when conductive structures are formed in the layer of insulating material, and an integrated circuit product that includes such a protection layer. One illustrative method disclosed herein includes, among other things, forming a layer of insulating material, performing at least one etching process through an overall masking layer to define an opening in the layer of insulating material, wherein the overall masking layer is comprised of a patterned metal-silicate masking layer that is positioned on and in contact with the layer of insulating material and a patterned masking layer positioned on and in contact with the patterned metal-silicate masking layer, depositing at least one conductive material in the opening in the layer of insulating material so as to over-fill the opening, and performing at least one planarization process so as to remove excess materials positioned outside of the opening above the patterned metal-silicate masking layer and thereby define a conductive structure that is positioned in the opening.

Another illustrative method disclosed herein includes, among other things, forming a metal-containing layer of material on and in contact with a layer of insulating material, forming at least one masking layer above the metal-containing layer of material, patterning the at least one masking layer so as to define a patterned masking layer that exposes portions of the metal-containing layer of material and, with the patterned masking layer in position, removing the exposed portions of the metal-containing layer of material to thereby define a patterned metal-containing masking layer that exposes portions of the layer of insulating material. In this embodiment, the method further includes performing an anneal process to convert the patterned metal-containing masking layer into a patterned metal-silicate masking layer, performing at least one etching process through at least the patterned metal-silicate masking layer so as to define an opening in the layer of insulating material, depositing at least one conductive material in the opening in the layer of insulating material so as to over-fill the opening, and performing at least one planarization process so as to remove excess materials positioned outside of the opening above the patterned metal-silicate masking layer and thereby define a conductive structure that is positioned in the opening.

A novel integrated circuit product disclosed herein includes, among other things, a layer of insulating material having an upper surface, a patterned metal-silicate layer positioned on and in contact with the upper surface of the layer of insulating material, an opening defined in the layer of insulating material and in the patterned metal-silicate layer and a conductive structure positioned in the opening, the conductive structure having an upper surface that is substantially planar with an upper surface of the patterned metal-silicate layer.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict various illustrative prior art hard mask layers used in forming conductive structures in a layer of insulating material and some problems that may be encountered using such prior art processing techniques; and

FIGS. 2A-2H depict various methods disclosed herein for methods of forming a protection layer on a layer of insulating material so as to protect the layer of insulating material when conductive structures are formed in the layer of insulating material, and an integrated circuit product that includes such a protection layer.

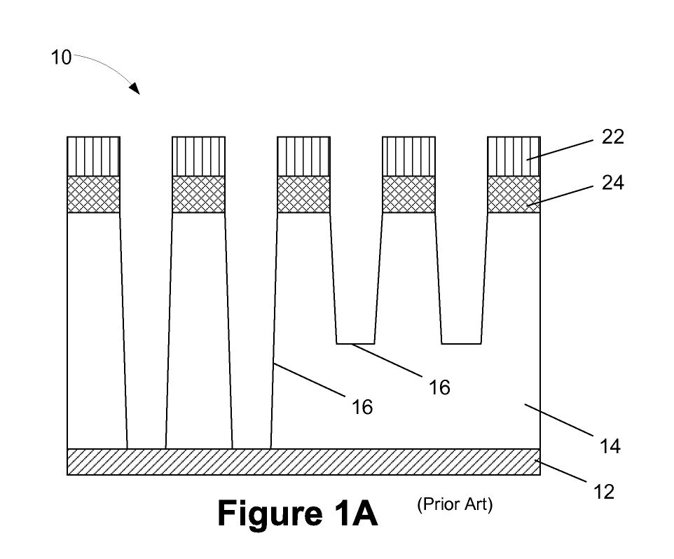

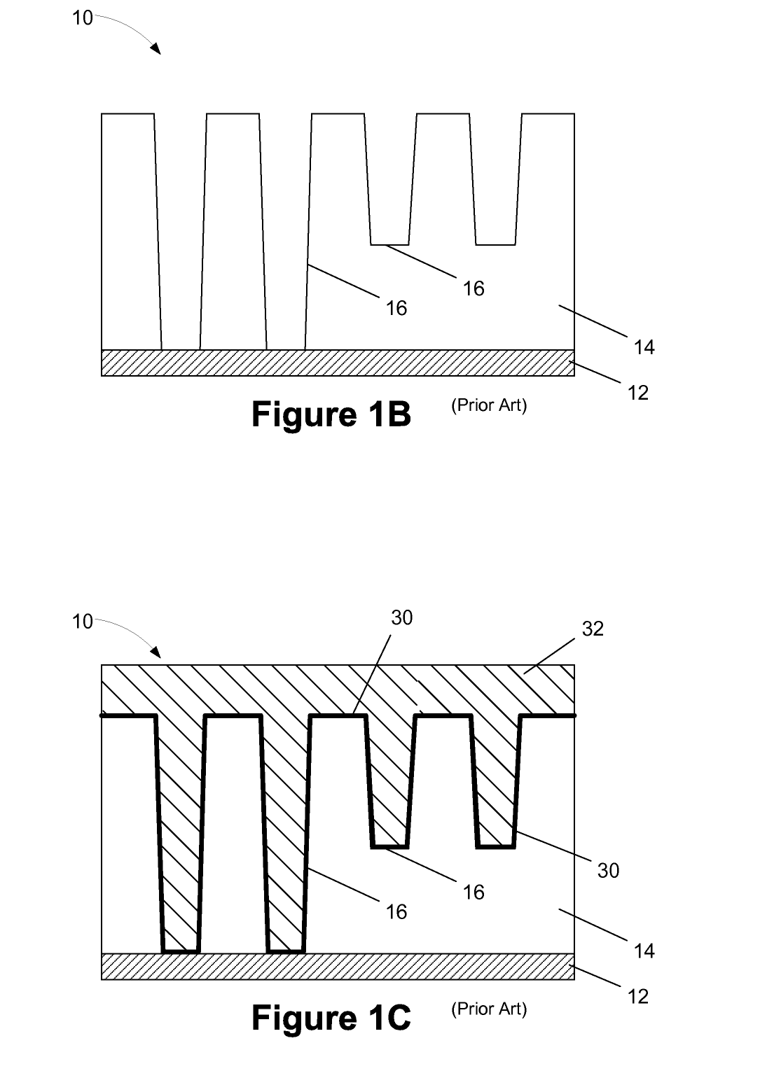

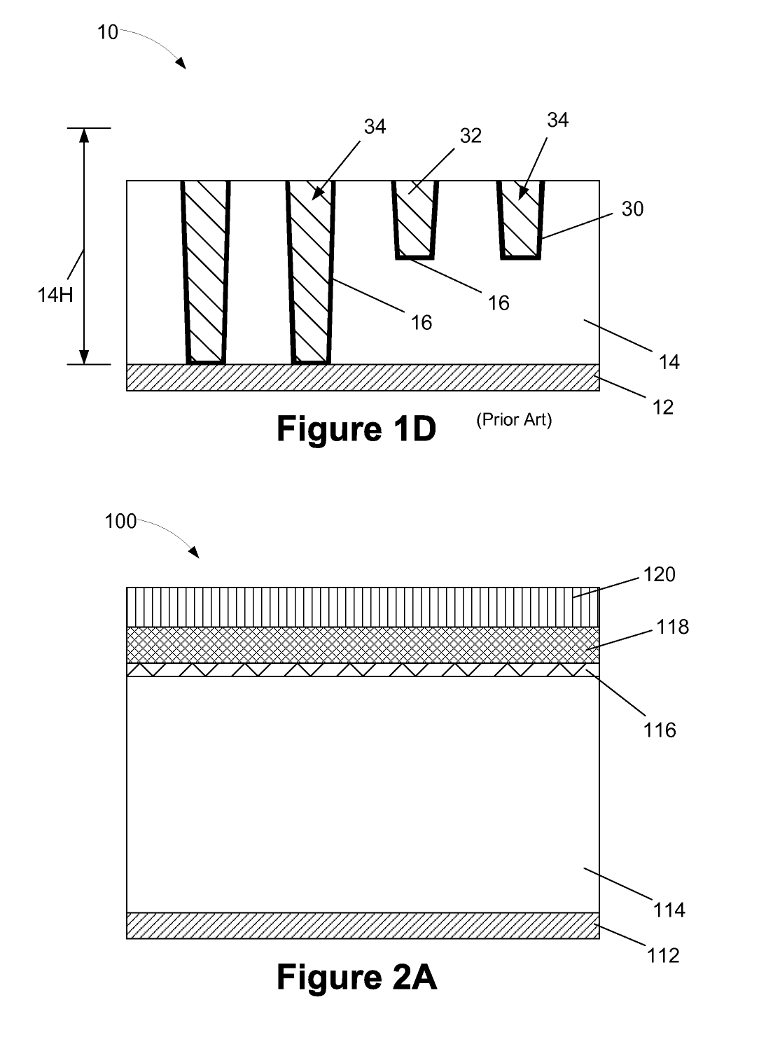

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming a protection layer on a layer of insulating material so as to protect the layer of insulating material when conductive structures are formed in the layer of insulating material, and an integrated circuit product that includes such a protection layer. As will be readily apparent to those skilled in the art upon a complete reading of the present application, the methods disclosed herein may be employed when forming conductive structures that contact a variety of different semiconductor devices, e.g., transistors, memory cells, resistors, etc., and may be employed when forming conductive structures for a variety of different integrated circuit products, including, but not limited to, ASIC's, logic devices, memory devices, etc. Moreover, the methods disclosed herein may be performed at any level in an integrated circuit product where conductive structures are formed. The various components and structures of the product 100 disclosed herein may be formed using a variety of different materials and by performing a variety of known techniques, e.g., a chemical vapor deposition (CVD) process, an atomic layer deposition (ALD) process, a thermal growth process, spin-coating techniques, etc. The thicknesses of these various layers of material may also vary depending upon the particular application. With reference to the attached drawings, various illustrative embodiments of the methods and products disclosed herein will now be described in more detail.

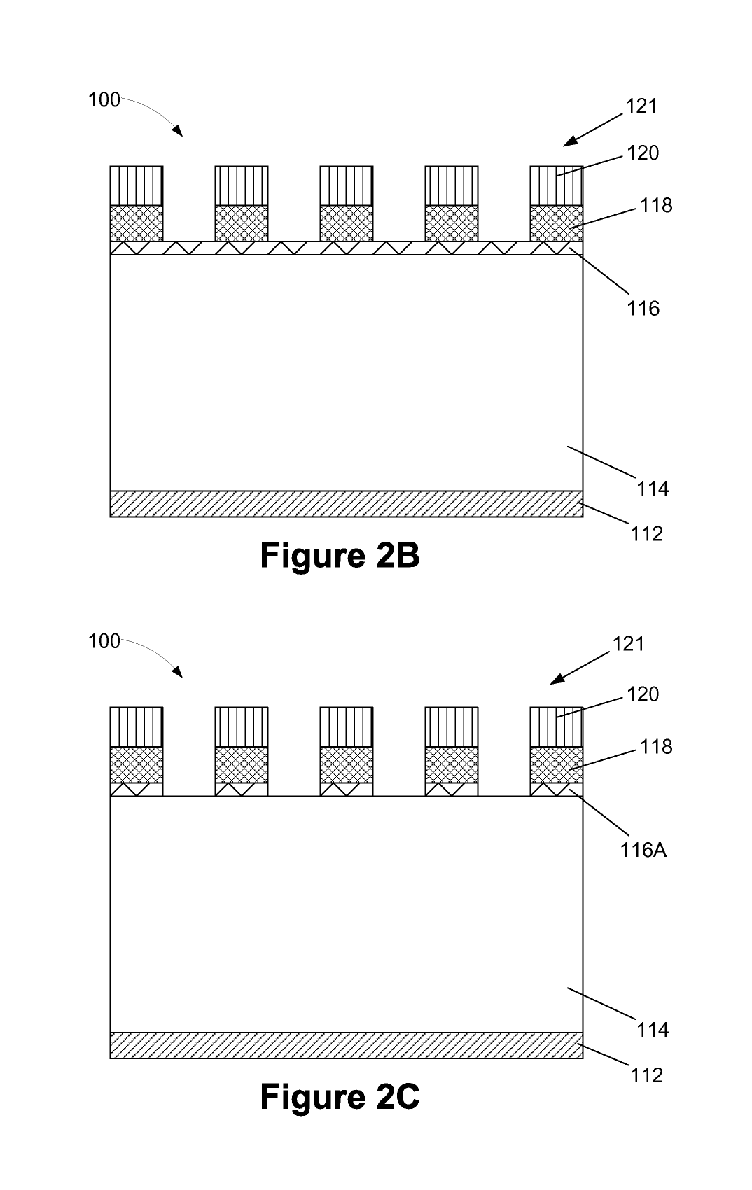

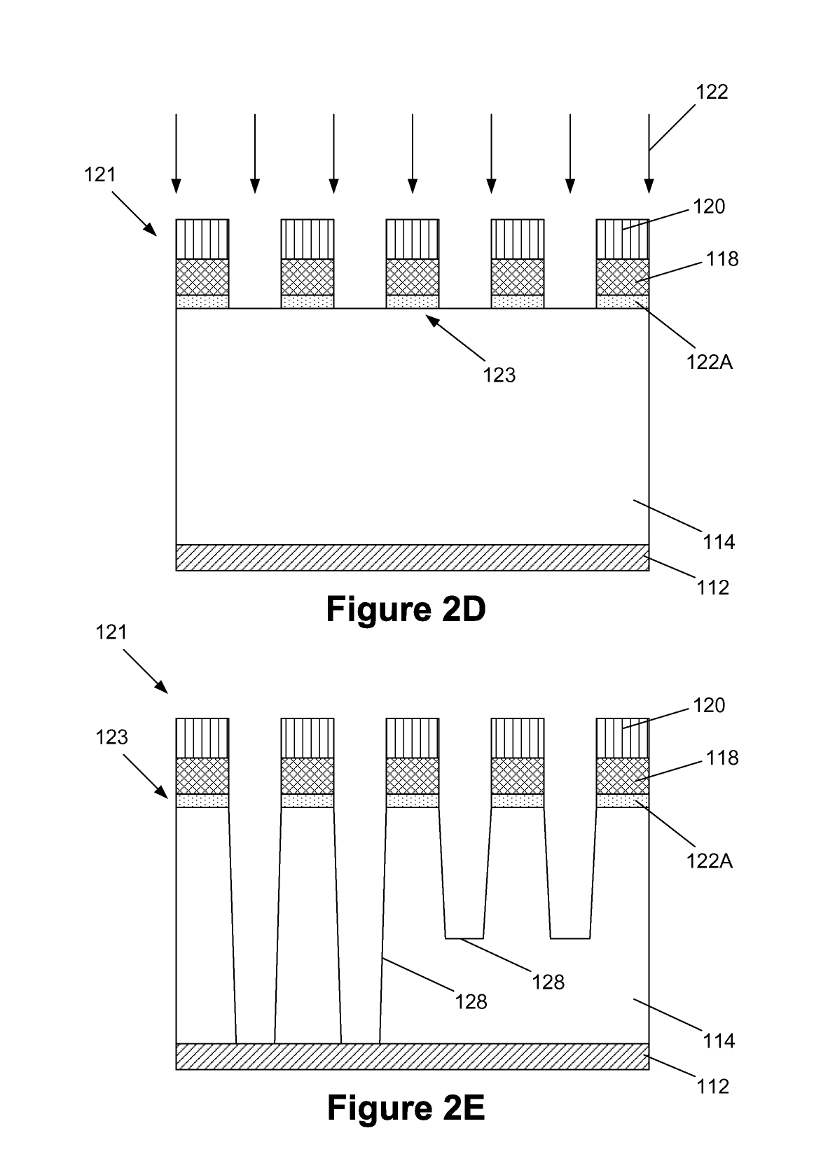

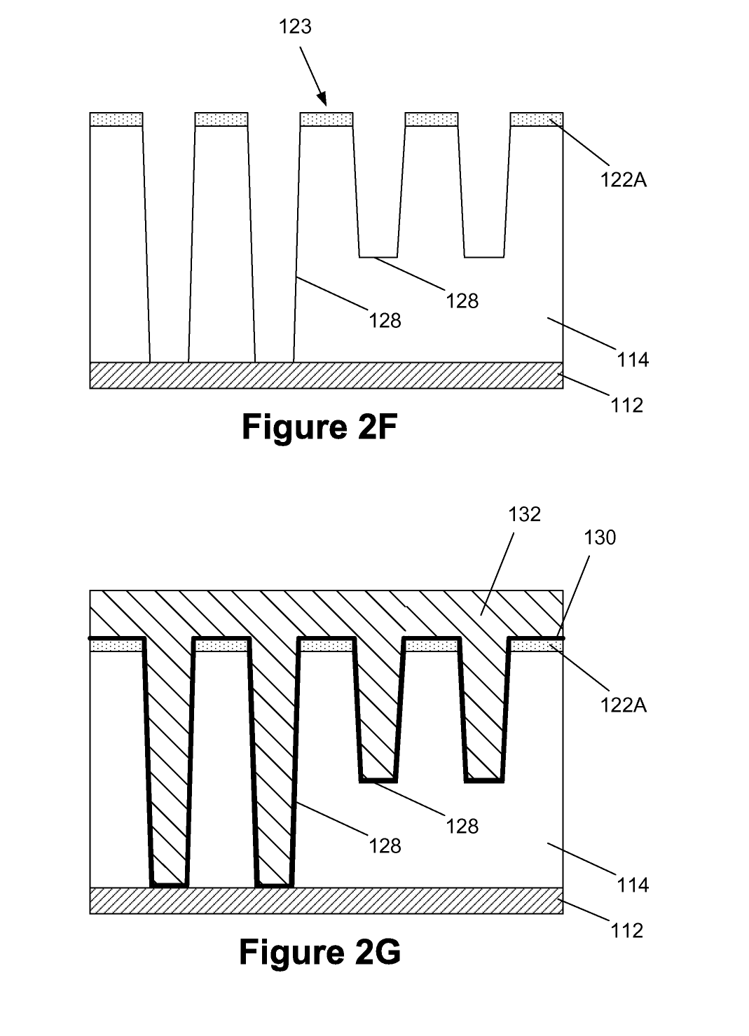

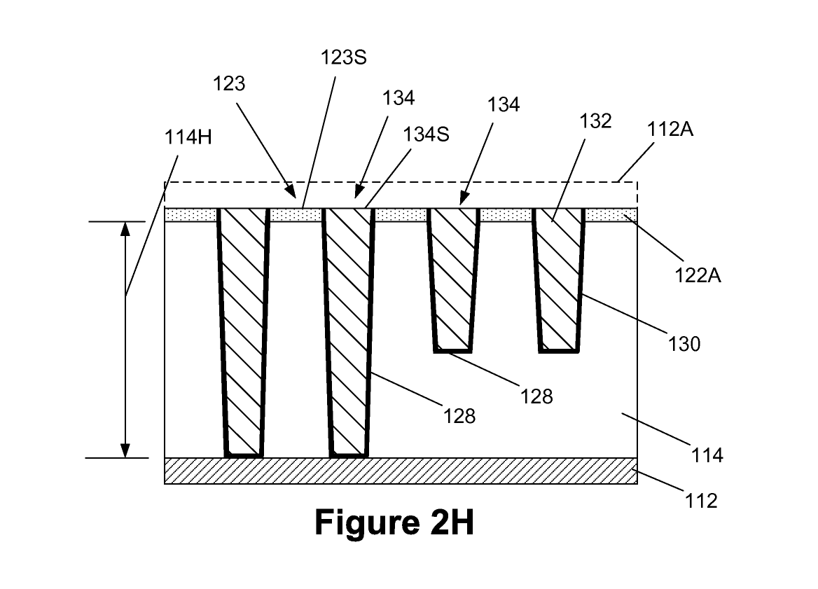

FIG. 2A depicts the integrated circuit product 100 at a point in processing wherein a metal-containing masking layer 116, a first masking layer 118 and a second masking layer 120 are sequentially formed above a layer of insulating material 114. In some embodiments, only a single masking layer, e.g., the first masking layer 118, may be formed above the metal-containing masking layer 116. In other applications, more than the two illustrative layers 118, 120 may be formed above the metal-containing masking layer 116. The product 100 may be any type of integrated circuit product that employs any type of a conductive structure, such as a contact or a conductive line or via, etc., commonly found on integrated circuit products. The conductive structures depicted, described and claimed in this application are intended to be representative in nature as they may represent any type of conductive feature or structure on an integrated circuit product. In the examples depicted herein, the conductive structures are depicted as having a representative barrier and/or adhesion layer. In practice, there may be one or more such barrier/adhesion layers used in a real-world device. The conductive structures described and discussed herein may be made of any type of conductive material, e.g., a metal or a metal alloy, such as copper or a copper-based material.

With continuing reference to FIG. 2A, the layer of insulating material 114 may be any type of insulating material, e.g., silicon dioxide, a low-k (k value less than 3.5) insulating material or an ultra-low-k (ULK) insulating material (k value less than 3.2), etc., it may be formed to any desired thickness and it may be formed by performing, for example, a CVD process. In one embodiment, the layer of insulating material 114 should be a material that is comprised of silicon and oxygen. In one illustrative embodiment, the metal-containing masking layer 116 may be comprised of a variety of materials, e.g., manganese, aluminum, nickel, titanium, etc., and it may be in the form of a substantially pure layer of metal, a metal alloy or metal compounds, including elements of the aforementioned metals with the possible addition of other elements, such a silicon, oxygen, and/or nitrogen. The metal-containing masking layer 116 may be relatively thin, e.g., about 2 nm, and it may be formed by performing a PVD process. In one illustrative embodiment, the first masking layer 118 may be comprised of a variety of materials, e.g., silicon nitride, etc., it may be formed to any desired thickness, and it may be formed by performing a CVD process. In one illustrative embodiment, where the first masking layer 118 is a silicon nitride material, it may also contain hydrogen (e.g., 2-10%). In one illustrative embodiment, the second masking layer 120 may be comprised of a variety of materials, e.g., titanium nitride, aluminum nitride, etc., it may be formed to any desired thickness, and it may be formed by performing a CVD or PVD process. In one illustrative embodiment, in depositing the layers 118 and 120, care should be taken to avoid or reduce oxygen contamination, e.g., the deposition temperatures should be lower than about 350° C.

FIG. 2B depicts the product 100 after one or more etching processes were performed through a patterned masking layer (not shown), such as a patterned layer of photo-resist material, positioned above the second masking layer 120 so as to pattern the first and second masking layers 118, 120. As depicted, the etching process ultimately stops on the metal-containing masking layer 116. These patterning operations result in the definition of a patterned masking layer 121 comprised of the patterned layers 118, 120.

FIG. 2C depicts the product 100 after the exposed portions of the metal-containing masking layer 116 were selectively removed relative to the surrounding structures and materials. The removal of the exposed portions of the metal-containing masking layer 116 exposed by the patterned masking layer 121 may be accomplished using a variety of techniques, e.g., wet or dry etching, wet cleaning, etc. In one embodiment, where the metal-containing masking layer 116 is comprised of manganese, a timed, wet cleaning process using diluted sulfuric acid (with a concentration of less than about 40% by weight) may be performed to effectively dissolve the exposed portions of the metal-containing masking layer 116. These process operations result in the definition of a patterned metal-containing masking layer 116A.

FIG. 2D depicts the product 100 after an anneal process 122 was performed on the product 100. In one embodiment, the anneal process 122 may be performed at a temperature that is equal to or greater than about 350° C. for a duration of about 1-120 minutes. The anneal process 122 may be a laser anneal process, an RTA process, a furnace anneal process, etc. During the anneal process 122, the remaining portions of the patterned metal-containing masking layer 116A are converted to a metal-silicate layer 122A, due to the reaction between the patterned metal-containing masking layer 116A and the layer of insulating material 114 on which it is formed. For example, in the case where the patterned metal-containing masking layer 116A is comprised of manganese, the metal-silicate layer 122A may be a 1-5 nm thick layer of manganese silicate (MnSiₓO_{y}). In other cases, the metal-silicate layer 122A may be aluminum silicate, nickel silicate or titanium silicate. These operations result in the definition of a patterned metal-silicate masking layer 123. This conversion is believed to occur due to the chemical reaction between the metal in the layer 116 (e.g., Mn) and the silicon and oxygen materials in the layer of insulating material 114.

FIG. 2E depicts the product 100 after one or more etching processes were performed though the overall masking layer, i.e., the combination of the patterned masking layer 121 and the patterned metal-silicate masking layer 123, to form a plurality of metallization or contact openings 128 in the layer of insulating material 114.

FIG. 2F depicts the product 100 after one or more etching processes were performed to remove the patterned masking layer 121, i.e., the first and second masking layers 118, 120, selectively relative to the surrounding structures and materials. This leaves the patterned metal-silicate masking layer 123 positioned above the layer of insulating material 114.

FIG. 2G depicts the product 100 after several process operations were performed. First, a schematically depicted barrier layer/adhesion layer 130 was formed on the product 100 and in the openings 128. In one embodiment, the barrier layer/adhesion layer 130 may be comprised of a first barrier layer (not separately shown) of tantalum nitride and a second adhesion layer (not separately shown) made of tantalum, both of which may be formed by performing sequential conformal deposition processes, e.g., ALD, PVD, etc. After the barrier layer/adhesion layer 130 is formed, a bulk conductive material layer 132, such as a copper-based material, is formed in the openings 128. Other materials, such as cobalt and ruthenium, may be employed as part of the barrier layer/adhesion layer 130.

FIG. 2H depicts the product 100 after one or more CMP process operations were performed to remove the excess conductive materials positioned outside of the openings 128 above the upper surface of the patterned metal-silicate masking layer 123. This results in the formation of the representative conductive structures 134, e.g., lines, vias, contacts, etc., in the layer of insulating material 114. As depicted, the conductive structure 134 has an upper surface 134S that is substantially planar with the upper surface 123S of the patterned metal-silicate masking layer 123. Using the methods disclosed herein, the patterned metal-silicate masking layer 123 protects the underlying layer of insulating material 114 during the various CMP process operations that were performed in manufacturing the conductive structures 134 by serving as a polish-stop layer during at least one of the CMP process operations. Thus, by using the methods disclosed herein, the CMP process operations do not consume the layer of insulating material 114 as it may still retain its originally as-formed thickness 114H. The patterned metal-containing masking layer 123 also prevents chemicals used during the CMP process operation from penetrating into the layer of insulating material 114. In some embodiments, at the point of processing depicted in FIG. 2H, the patterned metal-containing masking layer 123 may be selectively removed relative to the surrounding materials, and another level of conductive structures may be formed using the methods disclosed herein. In other embodiments, the patterned metal-containing masking layer 123 may remain in place, and another level of conductive structures may be formed above the metal-silicate layer 122A, i.e., another etch stop layer, such as the layer 112A (shown in dashed lines), may be formed on the patterned metal-containing masking layer 123, etc.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
forming a layer of insulating material;
performing at least one etching process through a patterned metal-silicate masking layer that is positioned on and in contact with said layer of insulating material and a patterned masking layer positioned on and in contact with said patterned metal-silicate masking layer so as to define an opening in said layer of insulating material;
depositing at least one conductive material in said opening in said layer of insulating material so as to over-fill said opening; and
performing at least one planarization process so as to remove excess materials positioned outside of said opening above said patterned metal-silicate masking layer and thereby define a conductive structure that is positioned in said opening.

2. The method of claim 1, further comprising removing said patterned metal-silicate masking layer and said patterned masking layer.

3. The method of claim 1, wherein, prior to depositing said at least one conductive material in said opening, the method comprises removing said patterned masking layer from above said patterned metal-silicate masking layer.

4. The method of claim 1, further comprising forming an etch stop layer above said patterned metal-silicate masking layer and said conductive structure.

5. The method of claim 1, wherein said layer of insulating material is comprised of one of a low-k (k value less than 3.5) insulating material or an ultra-low-k (ULK) insulating material (k value less than 3.2).

6. The method of claim 1, wherein said layer of insulating material is comprised of silicon and oxygen.

7. The method of claim 1, wherein said conductive structure is one of a conductive line, a conductive via or a conductive contact.

8. The method of claim 1, wherein depositing said at least one conductive material layer so as to over-fill said opening comprises depositing a copper-based material so as to over-fill said opening.

9. The method of claim 1, wherein depositing said at least one conductive material so as to over-fill said opening comprises forming at least one conductive barrier layer and at least one conductive adhesion layer in said opening, wherein said conductive barrier layer is comprised of tantalum nitride and said conductive adhesion layer comprises a layer of tantalum.

10. The method of claim 1, wherein said patterned masking layer is comprised of a first masking layer positioned on and in contact with said patterned metal-silicate masking layer and a second masking layer positioned on and in contact with said first masking layer.

11. The method of claim 10, wherein said first masking layer is a layer of silicon nitride that contains hydrogen and said second masking layer is a layer of titanium nitride.

12. The method of claim 1, wherein said patterned metal-silicate masking layer is comprised of one of manganese silicate, aluminum silicate, nickel silicate or titanium silicate.

13. A method, comprising:
forming a metal-containing layer of material on and in contact with a layer of insulating material;
forming at least one masking layer above said metal-containing layer of material;
patterning said at least one masking layer so as to define a patterned masking layer that exposes portions of said metal-containing layer of material;
with said patterned masking layer in position, removing said exposed portions of said metal-containing layer of material to thereby define a patterned metal-containing masking layer that exposes portions of said layer of insulating material;
performing an anneal process to convert said patterned metal-containing masking layer into a patterned metal-silicate masking layer;
performing at least one etching process through at least said patterned metal-silicate masking layer so as to define an opening in said layer of insulating material;
depositing at least one conductive material in said opening in said layer of insulating material so as to over-fill said opening; and
performing at least one planarization process so as to remove excess materials positioned outside of said opening above said patterned metal-silicate masking layer and thereby define a conductive structure that is positioned in said opening.

14. The method of claim 13, further comprising removing said patterned metal-silicate masking layer.

15. The method of claim 13, wherein, prior to depositing said at least one conductive material in said opening, the method comprises removing said patterned masking layer from above said patterned metal-silicate masking layer.

16. The method of claim 15, further comprising forming an etch stop layer above said patterned metal-silicate masking layer.

17. The method of claim 13, wherein performing said anneal process comprises performing said at least one anneal process at a temperature that is 350° C. or greater.

18. The method of claim 17, wherein said at least one anneal process is performed for a duration of at least 1 minute.

19. The method of claim 13, wherein forming said at least one masking layer comprises forming a first masking layer on and in contact with said metal-containing layer of material and forming a second masking layer on and in contact with said first masking layer.

20. The method of claim 19, wherein said first masking layer is a layer of silicon nitride that contains hydrogen and said second masking layer is a layer of titanium nitride.

21. The method of claim 19, wherein forming said first and second masking layers comprises forming said first and second masking layers at a temperature that is less than 350° C.

22. The method of claim 13, wherein said metal-containing layer of material is comprised of manganese and said patterned metal-silicate masking layer is comprised of manganese silicate.

23. The method of claim 13, wherein said layer of insulating material is comprised of silicon and oxygen.

24. A method, comprising:
forming a metal-containing layer of material on and in contact with a layer of insulating material, wherein said layer of insulating material is comprised of silicon and oxygen;
forming a first masking layer on and in contact with said metal-containing layer of material;
forming a second masking layer on and in contact with said first masking layer, wherein said first and second masking layers are formed at a temperature that is less than 350° C.;
patterning said first and second masking layers so as to define a patterned masking layer that exposes portions of said metal-containing layer of material;
with said patterned masking layer in position, removing said exposed portions of said metal-containing layer of material to thereby define a patterned metal-containing masking layer that exposes portions of said layer of insulating material;
performing an anneal process at a temperature that is 350° C. or greater for a duration of at least 1 minute to convert said patterned metal-containing masking layer into a patterned metal-silicate masking layer;
performing at least one etching process through at least said patterned metal-silicate masking layer so as to define an opening in said layer of insulating material;
depositing at least one conductive material in said opening in said layer of insulating material so as to over-fill said opening; and
performing at least one planarization process so as to remove excess materials positioned outside of said opening above said patterned metal-silicate masking layer and thereby define a conductive structure that is positioned in said opening.

25. A device, comprising:
a layer of insulating material having an upper surface;
a patterned metal-silicate layer positioned on and in contact with said upper surface of said layer of insulating material;
an opening defined in said layer of insulating material and in said patterned metal-silicate layer; and
a conductive structure positioned in said opening, said conductive structure having an upper surface that is substantially planar with an upper surface of said patterned metal-silicate layer.

26. The device of claim 25, wherein said conductive structure is comprised of copper.

27. The device of claim 25, wherein said patterned metal-silicate layer is comprised of manganese silicate.

28. The device of claim 25, further comprising an etch stop layer positioned on and in contact with said patterned metal-silicate layer.

29. The device of claim 25, wherein said conductive structure is one of a conductive line, a conductive via or a conductive contact.

30. The device of claim 25, wherein said layer of insulating material is comprised of one of a low-k (k value less than 3.5) insulating material or an ultra-low-k (ULK) insulating material (k value less than 3.2).

31. The device of claim 25, wherein said layer of insulating material is comprised of silicon and oxygen.
